(19) United States
(12) Patent Application Publication
(10) Pub. No.: US 2026/0344357 A1
(43) Pub. Date: Oct. 29, 2026

(54) MANUFACTURING APPARATUS AND MANUFACTURING METHOD OF SEMICONDUCTOR DEVICE

(71) Applicant: SHINKAWA LTD., Tokyo (JP)

(72) Inventors: Kohei Seyama, Tokyo (JP); Katsutoshi Nomura, Tokyo (JP)

(73) Assignee: SHINKAWA LTD., Tokyo (JP)

(21) Appl. No.: 18/995,918

(22) PCT Filed: Apr. 11, 2023
(86) PCT No.: PCT/JP2023/014709

§ 371 Date: Jan. 17, 2025

(30) Foreign Application Priority Data
Sep. 5, 2022 (JP) 2022-140936

(51) Int. Cl. H10P 72/70; H10W 72/00

(52) U.S. Cl. CPC H10P 72/7442; H10P 72/7402; H10P 72/7428; H10W 72/07141; H10W 72/07173; H10W 72/07183

(57) ABSTRACT

A manufacturing apparatus (10) of a semiconductor device includes: a wafer holding device (12) which holds one or more chips (100) adhesively held on a surface of a dicing tape (120) together with the dicing tape (120); a pickup head (14) which picks up a target chip (100); an energy irradiation device (16) which irradiates energy from a back side of the dicing tape (120) toward the target chip (100) to reduce adhesive force of the dicing tape (120); a temperature sensor (44) which detects a temperature in an irradiation area of the energy; and a controller (22). The controller (22) controls drive of the energy irradiation device (16) based on the detected temperature by the temperature sensor

### TECHNICAL FIELD

This specification discloses a manufacturing apparatus and a manufacturing method for manufacturing a semiconductor device by bonding a chip to a substrate.

### Description of Related Art

In manufacturing a semiconductor device, a chip is bonded to a substrate. Before bonding to the substrate, the chip is attached to a sheet body called a dicing tape. In the bonding process, a chip attached to the dicing tape is peeled off from the dicing tape and picked up using a pickup head. The picked up chip is bonded to the substrate by the pickup head.

In this regard, conventionally, to peel a chip from the dicing tape, it was common to apply mechanical force to the chip. For example, in the past, for peeling, the chip was pulled in a direction away from the dicing tape. However, in this case, the chip might be damaged due to the mechanical force applied.

In recent years, some have proposed using a non-contact pickup device that picks up the chip without contacting the chip. However, such a non-contact pickup device has small suction force, and therefore, the chip may be unable to be peeled off from the dicing tape with the non-contact pickup device.

Therefore, in some cases, some have proposed using a dicing tape having a self-peeling adhesive layer (for example, Patent Literature 1, Patent Literature 2, etc.). The self-peeling adhesive layer is a layer of which adhesive force decreases when energy, which is light or heat, is irradiated. By adhering the chip to such a dicing tape and irradiating energy immediately before pickup, the chip can be peeled off from the self-peeling type tape without applying mechanical load to the chip, even if the suction force of the pickup device is small.

### RELATED ART

### Patent Literature

Patent Literature 1: Japanese Patent Application Laid-Open No. 2007-194433
Patent Literature 2: Japanese Patent Application Laid-Open No. 2012-199442

### SUMMARY

### Technical Problem

However, in the case of using a self-peeling type dicing tape, energy in the form of light or heat is naturally irradiated onto the dicing tape. If the dicing tape or chip experiences excessive temperature rise due to the irradiation, it may lead to damage to the chip. Therefore, when using a self-peeling type dicing tape, it was needed to keep the amount of irradiated energy per unit time low to prevent the dicing tape and chip from becoming excessively hot. As a result, the time needed for peeling the chip has become prolonged, and consequently, the time needed for picking up the chip has become prolonged.

Therefore, this specification discloses a manufacturing apparatus and a manufacturing method of a semiconductor device that can further reduce the time needed for picking up a chip.

### Solution to the Problem

The manufacturing apparatus of a semiconductor device disclosed in this specification is a manufacturing apparatus for manufacturing a semiconductor device by picking up a chip from a dicing tape and bonding the chip to a bonding target, and includes: a wafer holding unit which holds one or more of the chips adhesively held on a surface of the dicing tape together with the dicing tape; a pickup head which picks up a target chip, which is a chip to be picked up among the one or more of the chips; an energy irradiation unit which irradiates energy, which is light or heat, toward the target chip from a back side of the dicing tape to reduce adhesive force of the dicing tape; a temperature sensor which detects a temperature in an irradiation area of the energy; and a controller. The controller controls drive of the energy irradiation unit based on a detected temperature by the temperature sensor.

In this case, the controller may perform feedback control on intensity of the energy so that the detected temperature becomes a specified target temperature, and the target temperature may be lower than the heat resistance temperature of each of the chip and the dicing tape.

Additionally, in response to a change in the detected temperature, the controller may determine that the target chip has been peeled from the dicing tape, cause the energy irradiation unit to decrease irradiation intensity of the energy, and cause the pickup head to pick up a target chip.

Moreover, the energy irradiation unit may include multiple light sources, and the temperature sensor may detect a temperature for each of irradiation areas divided from the target chip. The controller may independently control the light sources based on a temperature corresponding to the irradiation area.

A manufacturing method of a semiconductor device disclosed in this specification is a manufacturing method for manufacturing a semiconductor device by picking up a chip from a dicing tape and bonds the chip to a bonding target, and includes: in a state where the chip is adhesively held on a surface of the dicing tape, a target chip, which is a chip to be picked up, is irradiated with energy, which is light or heat, from a back side of the dicing tape to reduce adhesive force of the dicing tape; after adhesive force of an adhesive layer of the dicing tape decreases with irradiation of the energy irradiation, the target chip is picked up with a pickup head; and further, in parallel with the irradiation of the energy, a temperature in an irradiation area thereof is detected; and irradiation intensity of the energy is adjusted based on the temperature detected.

### Effects

According to the technology disclosed in this specification, the temperature in the irradiation area of the energy is detected, and the drive of the energy irradiation unit is controlled based on the detected temperature. Therefore, the target chip and the dicing tape can be prevented from becoming excessively hot. As a result, the intensity of the irradiation energy can be increased, the time required for peeling the target chip from the dicing tape can be reduced, and consequently, the time required for pickup can be reduced.

### BRIEF DESCRIPTION OF THE DRAWINGS

FIG. 1 is a diagram showing the configuration of a manufacturing apparatus.

FIG. 2 is a diagram showing the configuration of an energy irradiation device.

FIG. 3 is an image diagram showing the state immediately after irradiating energy to the dicing tape.

FIG. 4 is an image diagram showing the state where the chip is peeled off due to the irradiation of energy.

FIG. 5 is a flowchart showing the flow of the pickup process.

FIG. 6 is a timing chart of the pickup process according to the flow of FIG. 5.

FIG. 7 is a flowchart showing another example of the flow of the pickup process.

FIG. 8 is a timing chart of the pickup process according to the flow of FIG. 7.

FIG. 9 is a diagram showing an example of control of the irradiation intensity of energy.

FIG. 10 is a timing chart of the pickup process in a conventional example.

### DESCRIPTION OF EMBODIMENTS

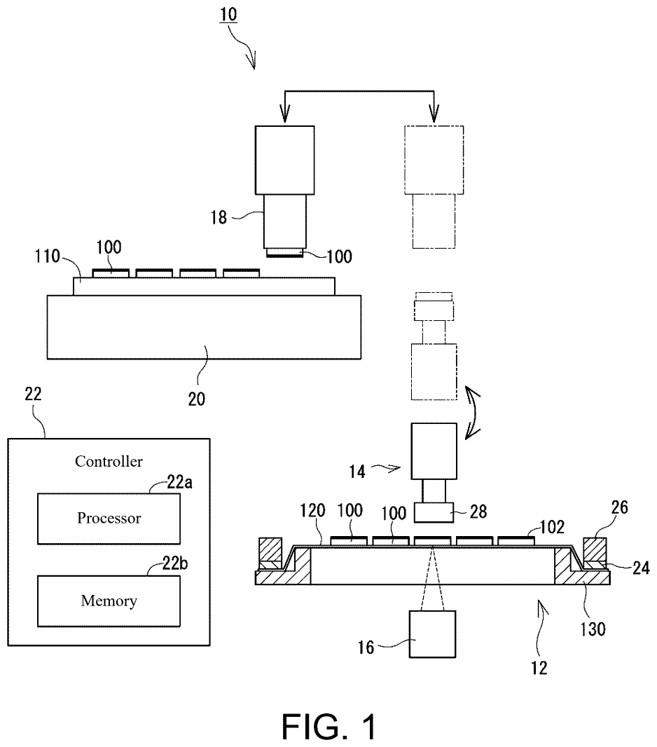

The configuration of a manufacturing apparatus 10 of a semiconductor device will be described below with reference to the drawings. FIG. 1 is a diagram showing the configuration of the manufacturing apparatus 10. The manufacturing apparatus 10 picks up a chip 100 from a dicing tape 120 and bonds the chip 100 to a bonding target, which is either a substrate 110 or another chip 100, to manufacture a semiconductor device. The chip 100 has a bonding material provided on a surface, and is bonded to the bonding target by pressing the surface against the bonding target. Hereinafter, the surface of the chip 100 on which the bonding material is formed is referred to as a “bonding surface 102,” and the opposite surface is referred to as a “holding surface 104.” In the following drawings, the bonding surface 102 is shown with a thick line.

When bonding the chip 100 to the bonding target, the chip 100 may be heated or may remain at room temperature. In other words, the bonding material of the chip 100 may be heated and melted, and the bonding material may be fused to the bonding target. Alternatively, in another form, the chip 100 may be bonded to the bonding target at room temperature using atomic bonding force or molecular bonding force.

To bond the chip 100 to the bonding target, the manufacturing apparatus 10 includes a mounting head 18 and a stage 20. The stage 20 is a platform on which the substrate 110 is placed. The mounting head 18 is disposed opposite to the stage 20 and suctions and holds the holding surface 104 of the chip 100 at the end thereof. In other words, the mounting head 18 holds the chip 100 so that the bonding surface 102 of the chip 100 faces the stage 20. By moving the mounting head 18 relative to the stage 20, the chip 100 is pressed against the bonding target.

To supply the chip 100 to the mounting head 18, the manufacturing apparatus 10 is further provided with a wafer holding device 12, a pickup device (hereinafter referred to as “PU device”) 14, and an energy irradiation device 16. The wafer holding device 12 holds a wafer together with the dicing tape 120. The wafer is previously attached to the dicing tape 120, then diced and divided into individual chips 100. As a result, multiple chips 100 are arranged on the surface of the dicing tape 120. As will be described in detail later, the dicing tape 120 includes a base material 122 and an adhesive layer 124, and holds individual chips 100 with the adhesive force of the adhesive layer 124. A wafer ring 130 is attached to the dicing tape 120 so as to surround the wafer. The chips 100 are held on the dicing tape 120 in a position where the holding surface 104 is in contact with the adhesive layer 124 and the bonding surface 102 faces upward (i.e., in a face-up position).

The wafer holding device 12 holds the dicing tape 120 while applying an outward tension in the planar direction, and includes an expand ring 24 and a ring holder 26. The expand ring 24 is an approximately cylindrical member with a through hole formed therethrough in the axial direction, and a flange extending radially outward is provided at the lower end thereof. The inner diameter of the expand ring 24 is larger than the diameter of the wafer and smaller than the inner diameter of the wafer ring 130.

The dicing tape 120 is placed on top of the expand ring 24. Additionally, the wafer ring 130 attached to the dicing tape 120 is pressed against the flange of the expand ring 24 by the ring holder 26 and fixed in place. At this time, the dicing tape 120 is in a state covering the upper end of the through hole of the expand ring 24, and the dicing tape 120 can be accessed from below via the through hole.

The PU device 14 holds and lifts the chip 100 in a face-up state and picks up the chip 100 from the dicing tape 120. After picking up, the PU device 14 changes the chip 100 to a face-down position and transfers the chip 100 directly or indirectly to the mounting head 18. As shown in FIG. 1, such a PU device 14 is disposed facing the bonding surface 102 of the chip 100 and has a PU head 28 that holds the bonding surface 102 of the chip 100 to be picked up (hereinafter referred to as the “target chip 100”). After picking up the target chip 100, the PU head 28 rotates 180 degrees, changing the target chip 100 to a face-down position. The PU device 14 then transfers the target chip 100 in the face-down position to the mounting head 18. In FIG. 1, the target chip 100 is shown being transferred directly from the PU device 14 to the mounting head 18, but the target chip 100 may also be transferred via other devices.

The energy irradiation device 16 is provided on the back side of the dicing tape 120, that is, on the opposite side to the PU device 14 with the dicing tape 120 in between. The energy irradiation device 16 irradiates energy towards the target chip 100 to reduce the adhesive force of the dicing tape 120. The type of energy is selected according to the characteristics of the adhesive layer 124 of the dicing tape 120. In the example, light, more specifically UV light, is irradiated as the energy. The reason for providing such an energy irradiation device 16 will be described later.

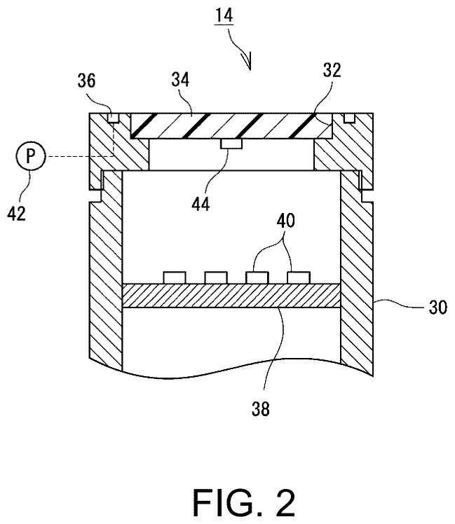

FIG. 2 is a diagram showing the configuration of the energy irradiation device 16. As shown in FIG. 2, the energy irradiation device 16 includes a cylindrical body 30. A circuit board 38 is attached inside the cylindrical body 30. Multiple light sources 40 are disposed in a matrix on the upper surface of the circuit board 38. The light source 40 is, for example, a UV LED that outputs UV light. A passage opening 32 is formed at the upper end of the cylindrical body 30. A lens 34 that transmits UV light is fitted into the passage opening 32.

Additionally, a suction groove 36 is formed on the upper end surface of the cylindrical body 30 so as to surround the periphery of the passage opening 32. The suction groove 36 is connected to a suction pump 42. When irradiating UV light on the target chip 100, the controller 22 brings the upper surface of the cylindrical body 30 into contact with the dicing tape 120 and drives the suction pump 42. As a result, the cylindrical body 30 adheres closely to the back surface of the dicing tape 120, and a portion of the heat generated in the dicing tape 120 and the target chip 100 is transferred to the cylindrical body 30, making it easier for the heat to be dissipated.

The energy irradiation device 16 further includes a temperature sensor 44 that detects the temperature of the target chip 100 in the irradiation area of the energy. The temperature sensor 44 is not particularly limited as long as it can directly or indirectly detect the temperature of the dicing tape 120 or the target chip 100. In the example of FIG. 2, the temperature sensor 44 is a contact temperature sensor, for example, a thermocouple, attached to the lower surface of the lens 34. Such a temperature sensor 44 may be a single sensor or multiple sensors may be provided. Additionally, the temperature sensor 44 may be a non-contact temperature sensor that detects temperature without contact, such as an infrared sensor. In this case, the infrared sensor may be incorporated into the circuit board 38 along with the light sources 40. In any case, the reason for providing such a temperature sensor 44 will be described in detail later.

In addition, the energy irradiation device 16 may irradiate UV light in an area selective manner. To enable area selective irradiation, the energy irradiation device 16 may change the position and/or orientation of the light source 40 (e.g., UV LED). As another configuration, the energy irradiation device 16 may include a mask member between the light source 40 and the dicing tape 120 to limit the irradiation area. Furthermore, as yet another configuration, the energy irradiation device 16 may include an optical member, such as a lens or prism, that changes the irradiation direction and/or irradiation range of the UV light output from the light source 40. In any case, the energy irradiation device 16 changes the irradiation position of the energy according to the position of the target chip 100.

The controller 22 controls the driving of the mounting head 18, the PU device 14, and the energy irradiation device 16 described above. Physically, the controller 22 is a computer having a processor 22a and a memory 22b.

As evident from the description so far, the chip 100 is adhesively held on the dicing tape 120. Therefore, when picking up the chip 100, it is needed to peel the chip 100 from the dicing tape 120. Conventionally, to peel the chip 100, mechanical force was often applied to the chip 100. Specifically, the chip 100 before peeling was often suctioned and held by the PU head 28, and the PU head 28 was raised. As the PU head 28 rises, force is applied to the chip 100 in a direction away from the dicing tape 120, and the force peels the chip 100 from the dicing tape 120. In this case, a load was applied to the chip 100, which could cause damage to the chip 100.

In recent years, to prevent mechanical contact between the PU head 28 and the bonding surface 102, a non-contact type PU head 28 has sometimes been used. The non-contact type PU head 28 may, for example, include an air-ejection type non-contact chuck that suctions the chip 100 by ejecting air radially or in a cyclone pattern, or may include an ultrasonic type non-contact chuck that suctions the chip 100 using ultrasonic waves. In any case, by using the non-contact type PU head 28, the quality degradation of the bonding surface 102 of the chip 100 can be suppressed. However, in the case of such a non-contact type PU head 28, due to the low suction force on the chip 100, the chip 100 could not be separated from the dicing tape 120.

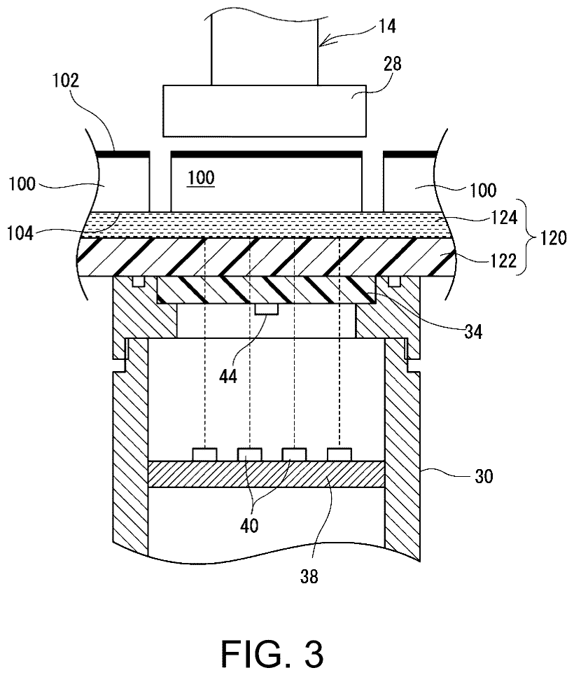

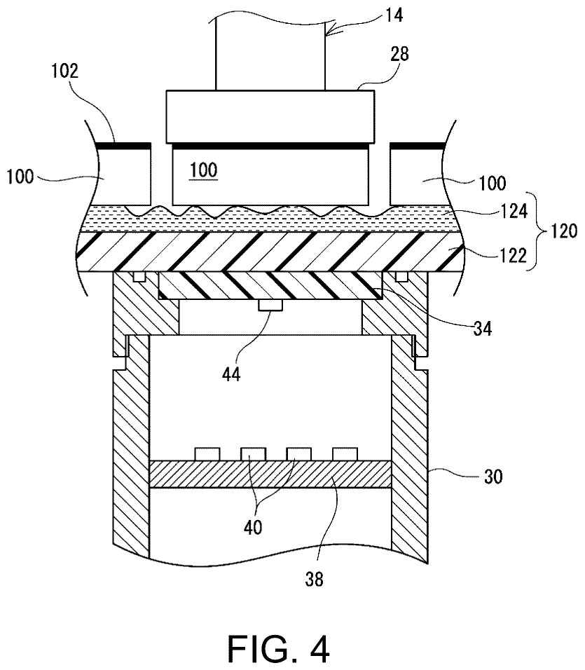

Therefore, in the example, to reduce the adhesive force of the dicing tape 120 prior to pickup, the energy irradiation device 16 is provided. Here, the dicing tape 120 handled in the example will be described. FIG. 3 and FIG. 4 are schematic diagrams showing the peeling of the chip 100 by the energy irradiation device 16.

As shown in FIG. 3 and FIG. 4, the dicing tape 120 is composed of a lamination of a base material 122 and an adhesive layer 124. The adhesive layer 124 is a UV self-peeling adhesive layer that loses adhesive force thereof when irradiated with energy, more specifically, UV light, and the target chip 100 is automatically peeled off. Such a UV self-peeling adhesive layer can be composed of, for example, a special acrylic polymer and a UV-functional gas-generating agent. When UV light is irradiated on the UV self-peeling adhesive layer, nitrogen gas is generated in the adhesive, and the gas is released to the outside of the adhesive and the adhesive surface interface. As the gas accumulates at the adhesive interface, the adhesion target naturally peels. The base material 122 merely needs to be able to transmit UV light, and may be composed of a sheet made of transparent resin such as polyacrylic, polyolefin, polycarbonate, polyvinyl chloride, ABS, polyethylene terephthalate (PET), nylon, polyurethane, polyimide, etc. Alternatively, the base material 122 may be composed of a sheet having a mesh-like structure, a sheet with holes, etc.

When UV light is irradiated by the energy irradiation device 16 to an area corresponding to the target chip 100 among such a dicing tape 120, as shown in FIG. 4, the adhesive force in the area is reduced, and gas is generated from the adhesive layer 124 in the area, causing the target chip 100 to automatically peel. As a result, the target chip 100 is peeled off from the dicing tape 120, allowing the target chip 100 to be picked up without applying a large load to the target chip 100, even with small suction force.

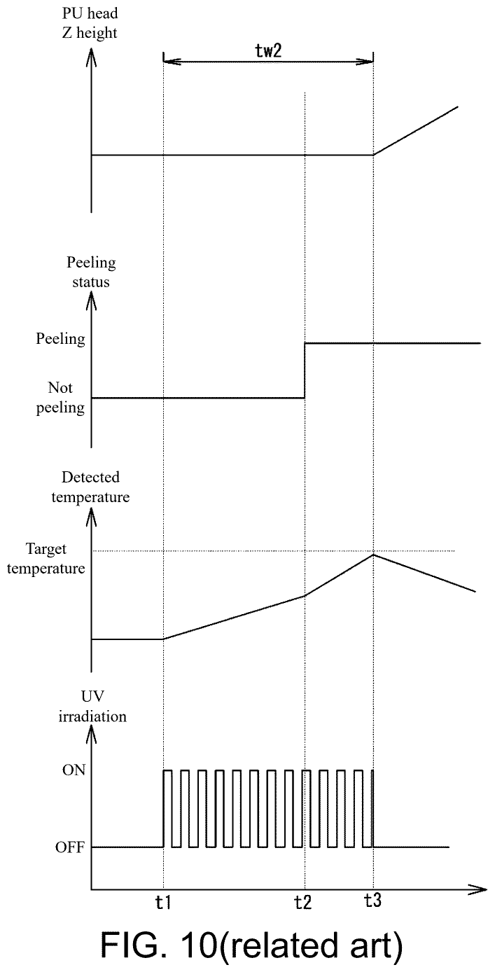

However, in the case of peeling using UV light, there has been a conventional issue that the process takes time, which will be described with reference to FIG. 10. FIG. 10 is a timing chart of the pickup process in a conventional example. In FIG. 10, the first row shows the Z position of the PU head 28, and the second row shows the peeling status of the target chip 100. Furthermore, the third row shows a detected temperature Td by the temperature sensor 44, and the fourth row shows the irradiation status of UV light by the energy irradiation device 16, respectively. It should be noted that in the conventional manufacturing apparatus 10, the temperature sensor 44 is not provided and the detected temperature Td is not detected, but in FIG. 10, the detected temperature Td is shown for comparison with the example.

In the conventional example of FIG. 10, to peel the chip 100 from the dicing tape 120, irradiation of UV light starts from time t1. When UV light is irradiated, the adhesive layer 124 of the dicing tape 120 gradually degrades, and the adhesive force decreases. Additionally, irradiating UV light generates heat in the dicing tape 120 and the chip 100. A portion of the heat is released to the outside air either directly or via the cylindrical body 30. However, in the case where the intensity of the UV light is high and the energy supply amount is higher compared to the heat dissipation rate, the target chip 100 or the dicing tape 120 might exceed the heat resistance temperature thereof and be damaged before the target chip 100 was peeled off.

Therefore, in the conventional example, to prevent the target chip 100 and the dicing tape 120 from exceeding the heat resistance temperature thereof before the target chip 100 is peeled off, the intensity of the UV light was kept low. In the conventional example of FIG. 10, the intensity of UV light was kept low by reducing a duty ratio D of the light source 40. As a result, as shown in FIG. 10, the temperature of the target chip 100 rises gradually. Meanwhile, as the target chip 100 gradually increases in temperature, the adhesive layer 124 of the dicing tape 120 is gradually degraded by the UV light. Consequently, at time t2, the target chip 100 is peeled off from the dicing tape 120.

However, in the conventional example, such peeling of the target chip 100 is unable to be detected, and pickup does not start until a predetermined waiting time has elapsed from the start of irradiation of UV light. In the conventional example of FIG. 10, pickup starts and the irradiation of UV light stops at time t3, which is after a predetermined waiting time tw2 has elapsed from time t1.

As shown in FIG. 10, after time t2 when the target chip 100 is peeled off, the rate of increase in the detected temperature Td increases. This is because when the target chip 100 is peeled off, the heat generated in the adhesive layer 124 becomes less likely to be transmitted to the target chip 100, and as a result, the rate of temperature rise of the dicing tape 120 increases.

As described above, in the conventional method, while the target chip 100 is reliably peeled off during the predetermined waiting time tw2, the irradiation intensity of the UV light was kept low to prevent the target chip 100 and the dicing tape 120 from exceeding the heat resistance temperature thereof. In this case, it naturally takes time until the pickup starts, which led to an increase in the time required for picking up the target chip 100 and consequently for manufacturing the semiconductor device.

Therefore, in the example, the temperature of the target chip 100 or the dicing tape 120 is detected directly or indirectly, and the intensity of UV light is feedback controlled so that the detected temperature Td does not exceed a specified target temperature T*. With the configuration, even if the irradiation intensity of UV light is increased, damage to the target chip 100 and other components can be prevented. Moreover, by increasing the irradiation intensity of UV light, the time required for peeling the target chip 100 can be reduced, and consequently, the time required for pickup can be reduced.

The target temperature T* is set to a value that does not exceed the heat resistance temperatures of both the target chip 100 and the dicing tape 120. To describe specifically, for example, let Ta be the heat resistance temperature of the target chip 100, Ea % be the maximum error of the detected temperature Td with respect to the actual temperature of the target chip 100, Tb be the heat resistance temperature of the dicing tape 120, and Eb % be the maximum error of the detected temperature Td with respect to the actual temperature of the dicing tape 120. In this case, the target temperature T* is set to a value that satisfies both T*x(1+Ea/100)<Ta and T*x(1+Eb/100)<Tb. In other words, the target temperature T* is lower than Ta/(1+Ea/100) and lower than Tb/(1+Eb/100).

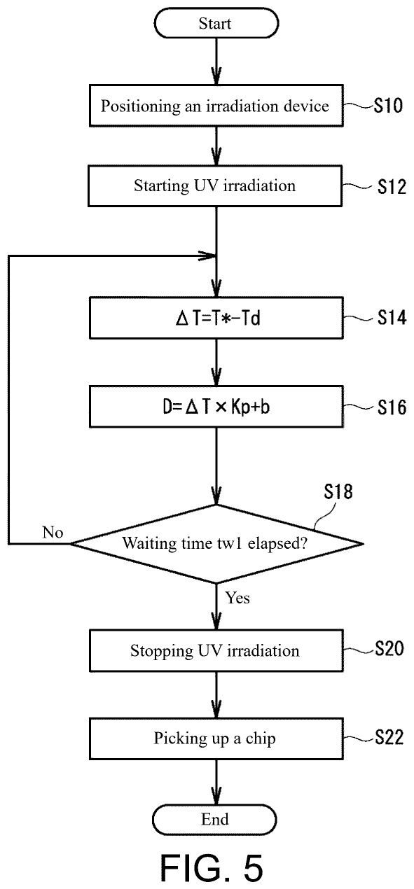

FIG. 5 is a flowchart showing the flow of the pickup process of the example. As shown in FIG. 5, the controller 22 first positions the energy irradiation device 16 with respect to the target chip 100 (S10). If the energy irradiation device 16 can be properly positioned with respect to the target chip 100, the controller 22 starts irradiation of UV light (S12). At this time, the duty ratio D is set to 100%.

Subsequently, the controller 22 performs feedback control of the duty ratio D using the detected temperature Td as a return value (S14 and S16). Specifically, the controller 22 calculates a deviation AT between the detected temperature Td and the target temperature T* (S14), and increases or decreases the duty ratio D in proportion to the deviation ΔT (S16). In other words, when the proportional gain is Kp and the bias is b, D=ΔT×Kp+b. It should be noted that depending on the value of the deviation ΔT, D may become greater than 100, but the duty ratio D is clipped at 100%.

The controller 22 continues the proportional feedback control of the duty ratio D until the elapsed time from the start of irradiation of UV light reaches a predetermined waiting time tw1 (S18). On the other hand, if the elapsed time reaches the predetermined waiting time tw1, the controller 22 stops the irradiation of UV light (S20) and drives the PU device 14 to start the pickup of the chip 100 (S22).

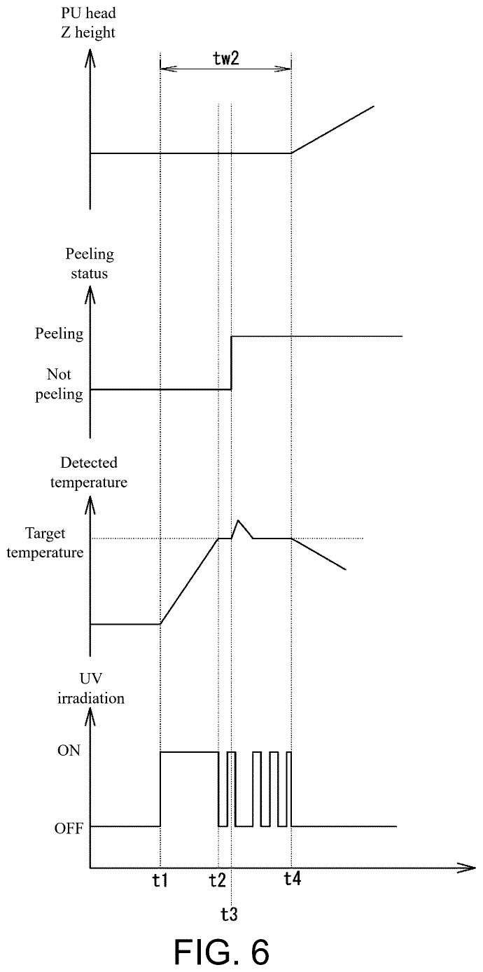

FIG. 6 is a timing chart of the pickup process of the example. In the example of FIG. 6, the irradiation of UV light starts at time t1. In the example, as described above, the duty ratio D is controlled by proportional feedback control using the detected temperature Td as a return value. Therefore, immediately after the start of the irradiation of UV light, the deviation AT is large, so the irradiation intensity of UV light is also kept high. In the example of FIG. 6, the duty ratio D is 100% until the detected temperature Td approaches the target temperature T*. As a result, the detected temperature Td, and consequently, the temperatures of the dicing tape 120 and the target chip 100 rise rapidly. At time t2, when the detected temperature Td reaches the target temperature T*, the deviation AT becomes smaller, so the controller 22 decreases the duty ratio D of the light source 40, thereby decreasing the irradiation intensity of UV light. This suppresses the temperature rise of the target chip 100 and prevents the target chip 100 and the dicing tape 120 from exceeding the heat resistance temperatures thereof. On the other hand, until reaching the target temperature T*, UV light is irradiated at high intensity, so the target chip 100 is peeled off from the dicing tape 120 relatively early. In the example of FIG. 6, the target chip 100 is peeled off from the dicing tape 120 at time t3.

On the other hand, at time t4 when the waiting time tw1 has elapsed from the start of irradiation of UV light, the target chip 100 is picked up and the irradiation of UV light is stopped. Here, the waiting time tw1 is set to a time that ensures the target chip 100 is certainly peeled off. As described above, in the example, UV light is irradiated at high intensity until reaching the target temperature T*, so the waiting time tw1 can be significantly shortened compared to the waiting time tw2 of the conventional example. As a result, according to the example, the time required for pickup can be reduced.

In the examples of FIG. 5 and FIG. 6, the pickup of the target chip 100 does not start until the waiting time tw1 has elapsed, even after the target chip 100 has been peeled off. However, the timing of peeling may be determined based on changes in the detected temperature Td, and if peeling is detected, pickup and stopping of the irradiation of UV light may be performed immediately.

In other words, as described above, when the target chip 100 is peeled off, heat transfer from the dicing tape 120 to the target chip 100 is inhibited, and the temperature of the dicing tape 120 temporarily increases rapidly, and consequently the detected temperature Td temporarily increases rapidly. In the case where the temporary rapid increase in the detected temperature Td occurs, it may be determined that the target chip 100 has been peeled off, and the pickup may be started and the irradiation of UV light may be stopped.

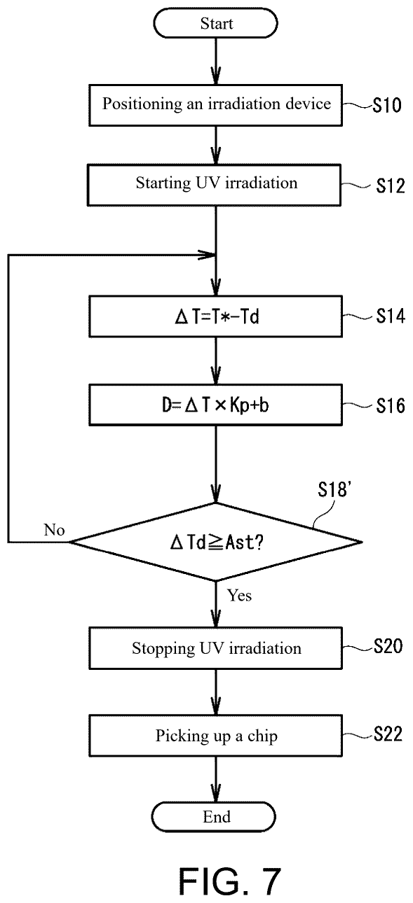

FIG. 7 is a flowchart of the pickup process in this case. In FIG. 7, the processes from step S10 to step S16 are the same as the processes in FIG. 5. On the other hand, in the example of FIG. 7, after determining the duty ratio D, the controller 22 compares a differential value ΔTd=Td[i]−Td[i−1] of the detected temperature Td with a predetermined reference value Ast (S18′). As a result of the comparison, if the differential value ΔTd is equal to or greater than the reference value Ast, the controller 22 determines that a rapid increase in the detected temperature Td has occurred, and consequently, peeling of the target chip 100 has occurred. In this case, the controller 22 stops the irradiation of UV light and initiates the pickup of the target chip 100 by the PU device 14 (S20 and S22).

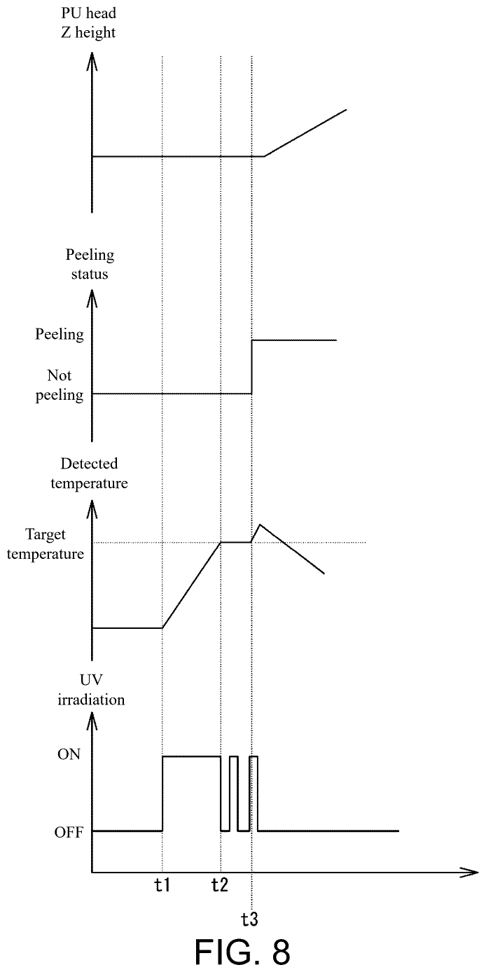

FIG. 8 is a timing chart of the pickup process according to the flow of FIG. 7. In the example of FIG. 8, at time t3, peeling of the target chip 100 occurs, and the detected temperature Td rises rapidly. If the rapid rise in the detected temperature Td is detected, the controller 22 immediately initiates the pickup and stops the irradiation of UV light. As a result, the time required for pickup can be further reduced.

As is clear from the above description, according to the technology disclosed in this specification, the temperatures of the target chip 100 and the dicing tape 120 are detected directly or indirectly, and the irradiation intensity of UV light is adjusted in response to the obtained detected temperature Td. As a result, the time required for pickup of the target chip 100 can be reduced while preventing damage to the target chip 100 and the dicing tape 120.

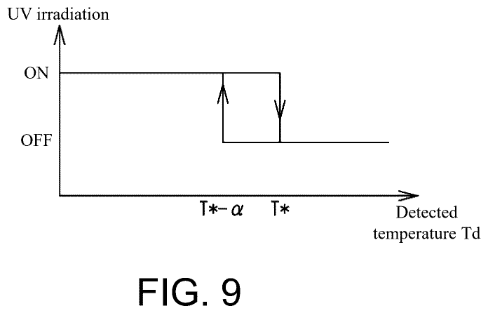

It should be noted that the configuration described so far is an example and may be modified as appropriate. For example, the control mode of the irradiation intensity of UV light may be changed as appropriate. For instance, instead of proportional control, the duty ratio D of the drive signal of the light source 40 may be controlled by proportional-integral control or proportional-integral-derivative control. Additionally, as another form, according to the switching chart of FIG. 9, when the detected temperature Td crosses the target temperature T* in the increasing direction, the light source 40 may be turned OFF, and when the detected temperature Td crosses the value (T*−α) in the decreasing direction, the light source 40 may be turned ON.

Additionally, multiple light sources 40 may be controlled independently of each other. For example, the detected temperature Td may be obtained for each of irradiation areas of each of the light sources 40. Then, the ON/OFF of each of the light sources 40 may be independently controlled in response to the detected temperature Td corresponding to the light source 40. By adopting such a configuration, variations in temperature distribution can be suppressed. In this case, to obtain multiple detected temperatures Td, multiple contact temperature sensors may be provided, or a single infrared sensor may be used to acquire the temperature distribution in the irradiation area as an image.

Moreover, in the above description, UV light is irradiated as energy, but the type of energy to be irradiated may be changed as appropriate in response to the characteristics of the dicing tape 120. For example, if the adhesive layer 124 of the dicing tape 120 is self-peeling due to heat, the energy irradiation device 16 may irradiate heat as energy.

### REFERENCE SIGNS LIST

10: Manufacturing apparatus; 12: Wafer holding device; 14: PU device; 16: Energy irradiation device; 18: Mounting head; 20: Stage; 22: Controller; 24: Expand ring; 26: Ring holder; 28: PU head; 30: Cylindrical body; 32: Passage opening; 34: Lens; 36: Suction groove; 38: Circuit board; 40: Light source; 42: Suction pump; 44: Temperature sensor; 100: Chip; 102: Bonding surface; 104: Holding surface; 110: Substrate; 120 Dicing tape; 122: Base material; 124: Adhesive layer; 130: Wafer ring

1. A manufacturing apparatus of a semiconductor device which is a manufacturing apparatus for manufacturing a semiconductor device by picking up a chip from a dicing tape comprising a UV self-peeling adhesive layer and bonding the chip to a bonding target, comprising:
a wafer holding unit, holding one or more of the chips adhesively held on a surface of the dicing tape together with the dicing tape;
a pickup head, picking up a target chip which is a chip to be picked up among the one or more of the chips;
an energy irradiation unit, irradiating energy, which is UV light, toward the target chip from a back side of the dicing tape to reduce adhesive force of the dicing tape;
a temperature sensor, detecting a temperature in an irradiation area of the energy; and
a controller, and
the controller controlling drive of the energy irradiation unit based on a detected temperature by the temperature sensor.

2. The manufacturing apparatus of a semiconductor device according to claim 1, wherein
the controller performs feedback control of intensity of the energy so that the detected temperature becomes a specified target temperature, and
the target temperature is lower than heat resistance temperatures of the chip and the dicing tape respectively.

3. The manufacturing apparatus of a semiconductor device according to claim 1, wherein
when the detected temperature rises rapidly after the detected temperature reaches a specified target temperature and irradiation intensity of the energy is reduced so as to suppress a temperature rise, the controller determines that the target chip has been peeled off from the dicing tape, causes the energy irradiation unit to further decrease irradiation intensity of energy, and causes the pickup head to pick up a target chip.

4. The manufacturing apparatus of a semiconductor device according to claim 1, wherein
the energy irradiation unit comprise a plurality of light sources,
the temperature sensor detects a temperature for each of irradiation areas divided from the target chip, and
the controller independently controls the plurality of light sources based on a temperature corresponding to the irradiation area.

5. A manufacturing method of a semiconductor device which is a manufacturing method for manufacturing a semiconductor device by picking up a chip from a dicing tape comprising a UV self-peeling adhesive layer and bonding the chip to a bonding target, comprising:
in a state where the chip is adhesively held on a surface of the dicing tape, irradiating energy, which is UV light, toward a target chip, which is a chip to be picked up, from a back side of the dicing tape to reduce adhesive force of the dicing tape;
after adhesive force of an adhesive layer of the dicing tape decreases with irradiation of the energy, picking up the target chip with a pickup head;
further,
in parallel with the irradiation of the energy, detecting a temperature in an irradiation area thereof; and
adjusting irradiation intensity of energy based on the temperature detected.
